(19) United States
(12) Patent Application Publication
(10) Pub. No.: US 2009/0057844 A1
(43) Pub. Date: Mar. 5, 2009

(54) SEMICONDUCTOR DEVICE AND METHOD OF MANUFACTURING SEMICONDUCTOR DEVICE

(75) Inventors: Kazumasa Tanida, Kawasaki-shi (JP); Masahiro Sekiguchi, Yokohama-shi (JP)

Correspondence Address: AMIN, TUROCY & CALVIN, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/203,389

(22) Filed: Sep. 3, 2008

(30) Foreign Application Priority Data
Sep. 4, 2007 (JP) 2007-229123

(51) Int. Cl. H01L 21/768; H01L 23/538

(52) U.S. Cl. 257/621; 438/667; 257/E23.174; 257/E21.597

(57) ABSTRACT

A semiconductor device 1 comprises a semiconductor substrate 2 having a through hole 3. A first insulation layer 4 having an opening 4a equal in diameter to the through hole 3 covers a front surface of the semiconductor substrate 2, and a first wiring layer 5 is formed thereon to cover the opening 4a. Further, a second insulation layer 6 is formed in the through hole 3 and on a rear surface of the semiconductor substrate 2. The second insulation layer 6 is formed to be in contact with an inner side of the first wiring layer 5 and has, in its contact portion, a plurality of small openings 6a smaller in diameter than the opening 4 of the first insulation layer 4. Further, a second wiring layer 7 is formed to fill the inside of the through hole 3, and the second wiring layer 7 is in contact with the inner side of the first wiring layer 5 via the small openings 6a of the second insulation layer 6.

### CROSS-REFERENCE TO RELATED APPLICATIONS

This application is based upon and claims the benefit of priority from the prior Japanese Patent Application No. 2007-229123, filed on Sep. 4, 2007; the entire contents of which are incorporated herein by reference.

### BACKGROUND OF THE INVENTION

1. Field of the Invention

The present invention relates to a semiconductor device and a method of manufacturing a semiconductor device, and more particularly, to a semiconductor device having a through connection part electrically connecting wirings on front and rear surfaces of a semiconductor substrate and a method of manufacturing the same.

2. Description of the Related Art

In a memory device using a semiconductor integrated circuit, it has been proposed to stack memory chips (semiconductor chips) in multi layers in order to increase memory capacity. In each of the semiconductor chips, through holes penetrating through front and rear surfaces are formed, a conductor layer is formed in the through holes, and metal bumps in electrical continuity with the conductor layer are provided on the rear surface. The metal bumps of the upper semiconductor chip are joined to metal pads formed on the front surface of the lower semiconductor chip, so that an integrated circuit portions of the upper memory chip and the lower memory chip are electrically connected.

As a semiconductor device having such through connection parts, there has conventionally been proposed a device in which wiring layers on a front surface and a rear surface of a semiconductor substrate are connected via conductive parts formed in through holes which are formed by etching from the rear surface of the semiconductor substrate (for example, U.S. Pat. No. 5,229,647, JP-B2 3186941 (Patent Publication)).

A conventional semiconductor device is described below. In a conventional semiconductor device 100 shown in FIG. 8, a semiconductor substrate 101 made of silicon has a through hole 102 penetrating through a front surface and a rear surface thereof, and an insulation film 103 is formed on an inner wall surface of the through hole 102 and continuously on the rear surface of the semiconductor substrate. A through wiring portion 104 is formed in the through hole 102. The through wiring portion 104 electrically connects a wiring layer (front surface side wiring layer) 105 formed on the front surface side of the semiconductor substrate 101 and an external terminal (solder ball) 106 formed on a rear surface side of the semiconductor substrate 101. An insulation layer (front surface side insulation layer) 107 is formed on the front surface of the semiconductor substrate 101, the front surface side wiring layer 105 is formed on the insulation layer 107, and a protection film (front surface side protection film) 108 is further formed thereon. On the front surface side of the semiconductor substrate 101, semiconductor devices such as image sensors are formed as integrated circuits. On the rear surface of the semiconductor substrate 101, the external terminal 106 connected to the through wiring portion 104, the insulation film (rear surface side insulation film) 103, and a rear surface side protection film 109 are formed. The external terminal 106 is formed to protrude to the outside.

In this semiconductor device 100, the through hole 102, a opening 107a of the front surface side insulation layer 107, and an opening of the rear surface side insulation film 103 have the same shape and diameter, and are formed in the following manner. The semiconductor substrate 101 is etched from its rear surface side by using a predetermined mask pattern (not shown) until the front surface side insulation layer 107 is exposed, whereby the through hole 102 is formed. Next, using the formed through hole 102 as a mask, the front surface side insulation layer 107 is etched by an etching method with a higher selective ratio relative to the semiconductor substrate 101, whereby the opening 107a of the front surface side insulation layer 107 is formed. Further, the rear surface side insulation film 103 is formed on the inner wall surfaces of the through hole 102 and the rear surface of the semiconductor substrate 101 so that its portion on the rear surface side of the semiconductor substrate 101 becomes larger in thickness than its portion on bottom surfaces and the inner wall surfaces of the through holes 102, and thereafter, the rear surface side insulation film 103 is etched back by anisotropic etching. In this manner, the insulation film 103 on the bottom surface of the through hole 102 is removed and thus the front surface side wiring layer 105 is exposed.

However, in the conventional semiconductor device 100 manufactured in such a method, if the adhesion between the exposed front surface side wiring layer 105 and the front surface side protection film 108 is not sufficient, the front surface side wiring layer 105 peels off the front surface side protection film 108 when the opening 107a is formed in the front surface side insulation layer 107, which sometimes results in deteriorated mechanical reliability. Another problem is that, when the opening is formed in the rear surface side insulation film 103, the front surface side wiring layer 105 easily bends due to a pressure difference at the time of the etching (plasma etching or the like) and breakage of the bent front surface side wiring layer 105 occurs to cause a connection failure, resulting in lowered yields.

### BRIEF SUMMARY OF THE INVENTION

A semiconductor device according to a first aspect of the present invention comprises: a semiconductor substrate; a through hole penetrating through a first surface and a second surface of the semiconductor substrate; a first insulation layer having an opening on a first surface side opening of the through hole, formed on the first surface of the semiconductor substrate; a first conductor layer formed on the first insulation layer to cover the opening; a second insulation layer having a plurality of small openings smaller in diameter than the opening of the first insulation layer, formed on an inner wall surface of the through hole and continuously on the second surface of the semiconductor substrate; and a second conductor layer formed to be in contact with an inner side of the first conductor layer via the small openings of the second insulation layer and to extend on the second insulation layer in the through hole and continuously on the second insulation layer on the second surface of the semiconductor substrate.

A semiconductor device according to a second aspect of the present invention comprises: a semiconductor substrate having a first surface and a second surface; a recessed hole formed from the second surface of the semiconductor substrate and having a depth smaller than a thickness of the semiconductor substrate; a plurality of small through holes formed on a bottom of the recessed hole to penetrate through a first surface side portion of the semiconductor substrate, and being smaller in diameter than the recessed hole; a first insulation layer formed on the first surface of the semiconductor substrate and having, on first surface side openings of the small through holes, small openings equal in diameter to the first surface side openings of the small through holes; a first conductor layer formed on the first insulation layer to cover the small openings; a second insulation layer which is formed to contact the first conductor layer internally via the small openings of the first insulation layer and to extend on inner wall surfaces of the recessed hole and the small through holes and continuously on the second surface of the semiconductor substrate, and which has, in the internal contact portion, a plurality of small openings substantially equal in diameter to the plural small openings of the first insulation layer; and a second conductor layer formed to be in contact with the inner side of the first conductor layer via the plural small openings of the second insulation layer and to extend on the second insulation layer in the recessed hole and the small through holes and continuously on the second insulation layer on the second surface of the semiconductor substrate.

A method of manufacturing a semiconductor device according to an aspect of the present invention comprises: forming a first insulation layer on a first surface of a semiconductor substrate; forming a first conductor layer on the first insulation layer; forming a through hole from a second surface side to the first surface side of the semiconductor substrate to expose the first insulation layer from a first surface side end of the through hole; forming an opening in the first insulation layer; forming a second insulation layer on an inner wall surface of the through hole and continuously on the second surface of the semiconductor substrate; forming a plurality of small openings in the second insulation layer to expose the first conductor layer; and forming a second conductor layer in a manner that the second conductor layer is in contact with an inner side of the first conductor layer via the small openings of the second insulation layer and extends on the second insulation layer in the through hole and continuously on the second insulation layer on the second surface of the semiconductor substrate.

According to the semiconductor device of the first aspect of the present invention, on the bottom of the through hole, the second insulation layer functions as a reinforcing structure for the first conductor layer. Therefore, no peeling or breakage of the first conductor layer occurs, resulting in improved electrical connection.

According to the semiconductor device of the second aspect of the present invention, the portion, of the semiconductor substrate, on the first surface side of the recessed hole (the portion has a thickness corresponding to a depth of the small through hole), together with the first insulation layer functions as a reinforcing structure for the first conductor layer, resulting in a further improved reinforcing effect, and therefore, a semiconductor device with still higher electrical and mechanical reliability can be obtained.

According to the method of manufacturing the semiconductor device according to the aspect of the present invention, a semiconductor device with high electrical and mechanical reliability can be obtained with high yields.

### BRIEF DESCRIPTION OF THE DRAWINGS

FIG. 1 is a cross-sectional view showing a configuration of a semiconductor device according to a first embodiment of the present invention.

FIG. 2A is a plane view showing an example of the shape of an opening of a second insulation layer in the first embodiment of the present invention.

FIG. 2B is a plane view showing another example of the shape of the opening of the second insulation layer in the first embodiment of the present invention.

FIG. 3A to FIG. 3H are cross-sectional views illustrating a method of manufacturing the semiconductor device according to the first embodiment of the present invention.

FIG. 4 is a cross-sectional view showing a configuration of a semiconductor device according to a second embodiment of the present invention.

FIG. 5A to FIG. 5G are cross-sectional views illustrating a method of manufacturing the semiconductor device according to the second embodiment of the present invention.

FIG. 6 is a cross-sectional view showing a configuration of a semiconductor device according to a third embodiment of the present invention.

FIG. 7A to FIG. 7I are cross-sectional views illustrating a method of manufacturing the semiconductor device according to the third embodiment of the present invention.

FIG. 8 is a cross-sectional view showing a configuration of a conventional semiconductor device.

### DETAILED DESCRIPTION OF THE INVENTION

Hereinafter, embodiments for carrying out the present invention will be described. The embodiments will be described below based on the drawings, but these drawings are provided only for an illustrative purpose and are not intended to limit the present invention.

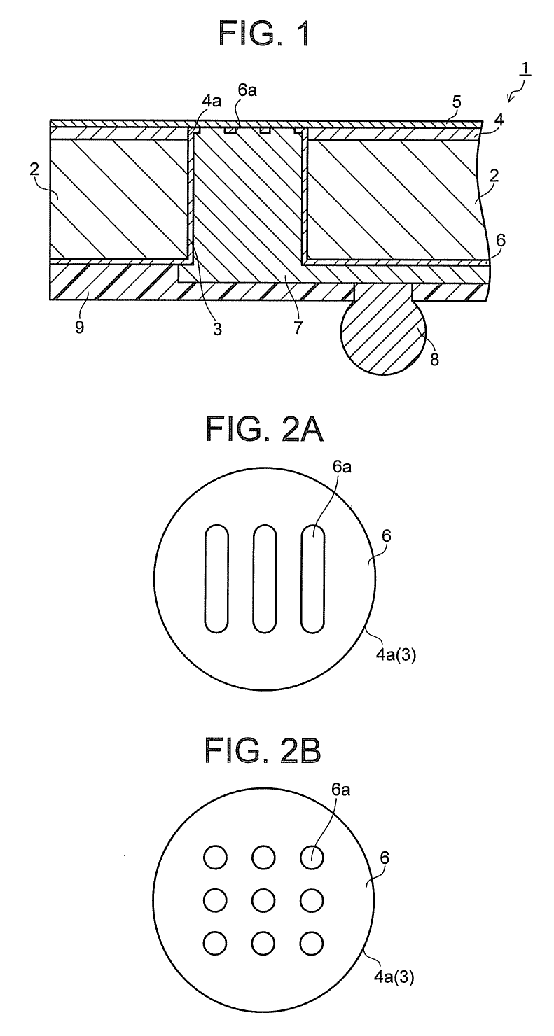

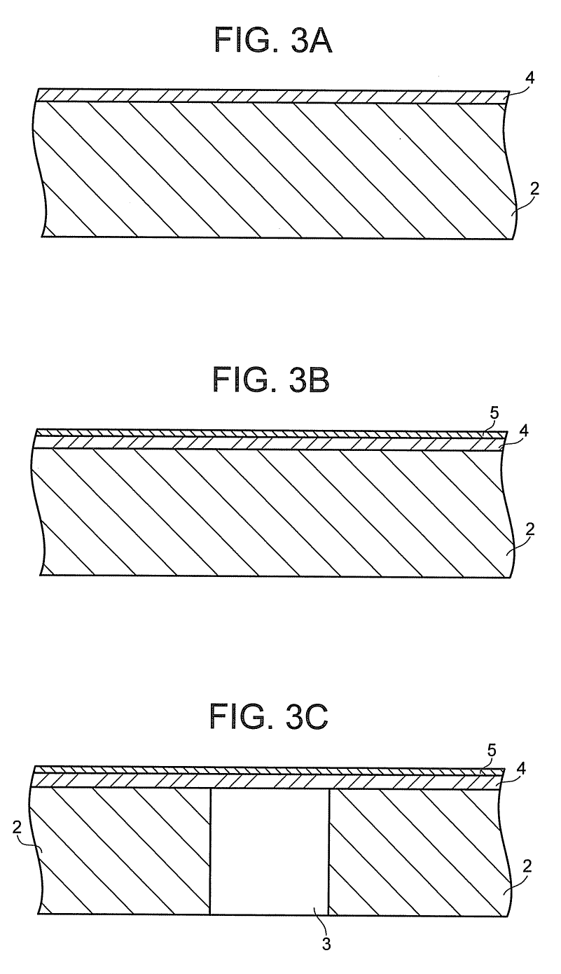

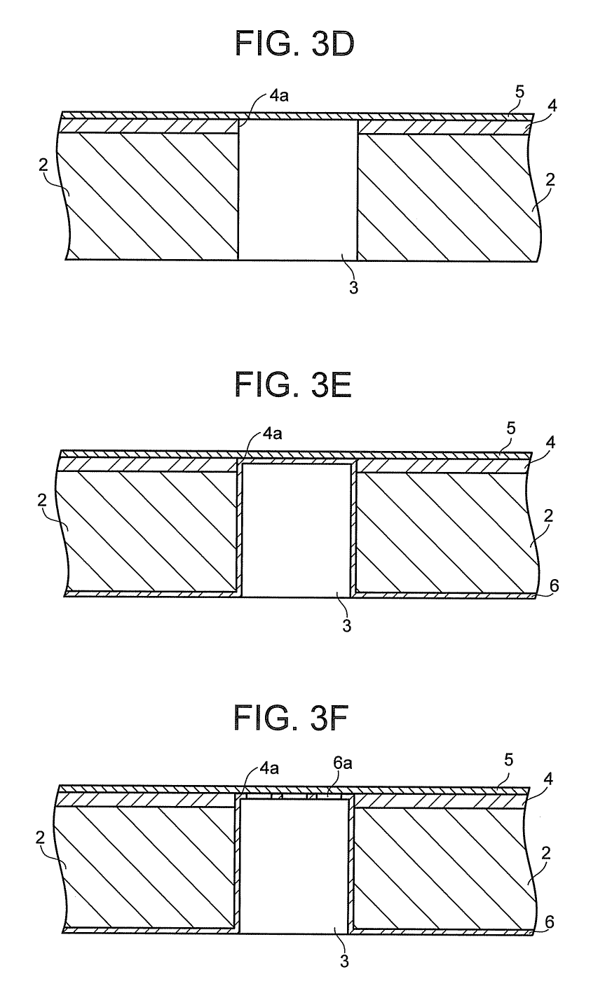

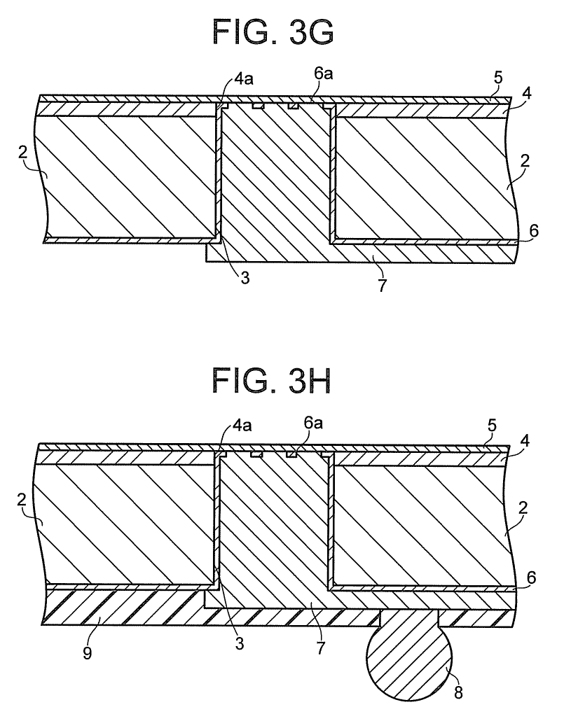

FIG. 1 is a cross-sectional view showing a configuration of a semiconductor device according to a first embodiment of the present invention, and FIG. 2A and FIG. 2B are plane views showing examples of the shape of an opening of a second insulation layer in the first embodiment. FIG. 3A to FIG. 3H are cross-sectional views showing steps in a method of manufacturing the semiconductor device in the first embodiment.

As shown in FIG. 1, a semiconductor device 1 of the first embodiment has a semiconductor substrate 2 such as a silicon substrate, and the semiconductor substrate 2 has a through hole 3 is formed to penetrate through a front surface (element region formation surface) as a first surface and a rear surface as a second surface. A first insulation layer 4 covers the front surface of the semiconductor substrate 2, the first insulation layer 4 having, on an upper portion (front surface side end) of each of the through hole 3, an opening 4a equal in diameter to the through hole 3. On the first insulation layer 4, a wiring layer 5 as a first conductor layer is formed. The first wiring layer 5 is formed to cover and close the opening 4a of the first insulation layer 4. Further, a second insulation layer 6 is formed on inner wall surfaces of the through hole 3 and on the rear surface of the semiconductor substrate 2. The second insulation layer 6 is formed to be in contact with an inner side of the first wiring layer 5, and each of its contact portions has a plurality of small openings 6a smaller in diameter than the opening 4a of the first insulation layer 4.

FIG. 2A and FIG. 2B show examples of the shape and disposition of the plural small openings 6a of the second insulation layer 6. The shape of the small openings 6a is not specifically limited and may be a circle, an ellipse, a quadrangle, a pentagon, a polygon with more than five sides, or the like. Further, the number of the small openings 6a and the way they are disposed are not specifically limited. They may be disposed at random but are preferably disposed in a predetermined pattern, such as in one direction or in vertical and lateral directions (xy directions). In particular, disposing the small openings 6a at lattice points of the x axis and the y axis as shown in FIG. 2B has a great advantage of a high reinforcing effect since the effect of reinforcing the first wiring layer 5 is exhibited in a well-balanced manner both in the xy directions.

A wiring layer 7 as a second conductor layer is formed to fill the inside of the through hole 3. This second wiring layer 7 is in contact with the inner side of the first wiring layer 5 via the plural small openings 6a of the second insulation layer 6 and is formed on the second insulation layer 6 in the through hole 3 and continuously on the second insulation layer 6 on the rear surface of the semiconductor substrate 2. Further, an external terminal 8 is provided on the second wiring layer 7 on the rear surface of the semiconductor substrate 2, and on the rear surface of the semiconductor substrate 2, a protection layer 9 (rear surface side protection layer) 9 is formed on the second wiring layer 7 except its portion where the external terminal 8 is provided and on the second insulation layer 6.

On the first wiring layer 5 on the front surface of the semiconductor substrate 2, a front surface side protection film is formed, though not shown. Between the first wiring layer 5 and the front surface side protection film, a multilayer wiring structure in which an insulation layer and a wiring layer are provided may be further formed. When the semiconductor device 1 is in a form of an image sensor package, a light-transmitting protection substrate of glass or the like is formed on the front surface of the semiconductor substrate 2 via a bonding layer, but is not shown for simplification of the description. The same applies to the embodiments below.

The semiconductor device 1 of the first embodiment is manufactured in the following manner. In a first step shown in FIG. 3A, the first insulation layer 4 is formed on the front surface (first surface) of the semiconductor substrate 2 by a CVD (Chemical Vapor Deposition) method, a spin coating method, a spray coating method, or the like. The first insulation layer 4 is comprised of, for example, silicon oxide (SiO₂), silicon nitride (SiNₓ), SiOF (Fluorine-doped SiO₂), porous SiOC (Carbon-doped SiO₂), or the like.

Next, in a second step shown in FIG. 3B, the first wiring layer 5 is formed on the first insulation layer 4 by a sputtering method, a CVD method, a vapor deposition method, a plating method, or the like. The first wiring layer 5 is, for example, a single layer comprised of a high-resistance metal (Ti, TiN, TiW, Ni, Cr, TaN, COWP, or the like) or a low-resistance metal (Al, Al—Cu, Al—Si—Cu, Cu, Au, Ag, or the like), or has a structure in which a plurality of layers comprised of the aforethe material are stacked.

Incidentally, after the first wiring layer 5 is formed, the front surface side protection film, though not shown, is formed thereon. The front surface side protection film is comprised of SiO₂, SiNₓ, polyimide resin, epoxyresin, or a solder resist material, and is formed by, for example, a CVD method, a spin coating method, a spray coating method, a printing method, or the like. In the multilayer wiring structure in which the insulation layers and the wiring layers are formed between the first wiring layer 5 and the front surface side protection film, the insulation layers and the wiring layers are formed by a CVD method, a sputtering method, a vapor deposition method, a plating method, or the like. When the multilayer wiring structure is formed, the steps shown in FIG. 3A and FIG. 3B are repeated, and the wiring layers are mutually electrically connected by metal vias, not shown. Further, when the semiconductor device 1 is in the form of the image sensor package, the light-transmitting protection substrate of glass or the like is bonded on the front surface of the semiconductor substrate 2 via the bonding layer (for example, photosensitive or non-photosensitive epoxy resin, polyimide resin, acrylic resin, silicone resin).

Next, in a third step shown in FIG. 3C, the through hole 3 is formed from the rear surface side of the semiconductor substrate 2 by a plasma etching method by using a mask (not shown) with a predetermined pattern to expose the first insulation layer 4 from a bottom surface of the through hole 3. The through hole 3 preferably has a cross section tapering toward the first insulation layer 4. In the plasma etching for forming the through hole 3, etching gas is introduced into plasma so that the semiconductor substrate 2 is etched to a relatively larger extent than the first insulation layer 4. As the etching gas, mixed gas of SF₆, O₂, and Ar is used, for instance, when the semiconductor substrate 2 is a silicon (Si) substrate and the first insulation layer 4 is a SiO₂ film.

Next, in a fourth step shown in FIG. 3D, an exposed portion of the first insulation layer 4 is removed by plasma etching, whereby the opening 4a is formed in the first insulation layer 4 to expose the first wiring layer 5. In this plasma etching, etching gas (for example, mixed gas of C₅F₈, O₂, and Ar when the first insulation layer 4 is a SiO₂ film, the semiconductor substrate 2 is a silicon substrate, and the first wiring layer 5 is comprised of TiN or Al) is introduced into plasma so that the first insulation layer 4 is etched to a relatively larger extent than the semiconductor substrate 2 and the first wiring layer 5.

The aforethe third and fourth steps can be performed at a time by a laser etching method without using a mask. As a laser beam source, YAG (yittrium/aluminum/garnet) laser, UV (solid ultraviolet) laser, excimer laser, carbon dioxide gas (CO₂) laser, or the like is used, for instance. A wavelength band of the YAG laser is 355 nm, a wavelength band of the UV laser is 213 nm, 266 nm (CLBO: cesium lithium tri-borate crystal), and 355 nm (CBO: cesium tri-borate crystal, LBO: lithium tri-borate crystal), and a wavelength band of the excimer laser is 193 m (ArF), 248 nm (KrF), 308 nm (XeCl), and 351 nm (XeF). When the semiconductor substrate 2 is a silicon substrate and the first insulation layer 4 is a SiO₂ film, the YAG laser with the 355 nm wavelength is preferably used as the laser beam source.

In a fifth step shown in FIG. 3E, the second insulation layer 6 is formed by a CVD method, a spray coating method, a spin coating method, a film laminating method, or the like to cover the bottom surface (exposed portion of the first wiring layer 5) and the inner wall surface of the through hole 3, and the rear surface of the semiconductor substrate 2. The second insulation layer 6 is comprised of, for example, silicon oxide, silicon nitride, polyimide resin, BCB (benzocyclobuten) resin, epoxy resin, or the like.

In a sixth step shown in FIG. 3F, by plasma etching using a mask (not shown) with a predetermined pattern, the plural small openings 6a smaller in diameter than the opening 4a of the first insulation layer 4 are formed in the second insulation layer 6, which is positioned on the bottom surfaces of the through hole 3 to cover the first wiring layer 5, thereby exposing the first wiring layer 5 again from the small openings 6a. In this plasma etching for forming the small openings 6a, etching gas (for example, mixed gas of C₅F₈, O₂, and Ar when the second insulation layer 6 is a SiO₂ film and the first wiring layer 5 is comprised of TiN or Al) is introduced into plasma so that the second insulation layer 6 is etched to a relatively larger extent than the first wiring layer 5.

Alternatively, the step of removing the portions of the second insulation layer 6 to form the small openings 6a can be performed by a laser etching method, without using any mask. As a laser beam source, YAG laser, UV laser, excimer laser, carbon dioxide (CO₂) laser, or the like is used, for instance. When the second insulation layer 6 is a resin film and the small openings 6a with an especially minute diameter are formed, UV laser with a 266 nm wavelength is preferably used.

Then, in a seventh step shown in FIG. 3G, the second wiring layer 7 is formed to be in contact with the inner side of the first wiring layer 5 via the small openings 6a of the second insulation layer 6 and to extend on the second insulation layer 6 in the through hole 3 and continuously on the second insulation layer 6 on the rear surface of the semiconductor substrate 2. The second wiring layer 7 is, for example, a single layer comprised of a high-resistance metal (Ti, TiN, TiW, Ni, Cr, TaN, COWP, or the like), a low-resistance metal (Al, Al—Cu, Al—Si—Cu, Cu, Au, Ag, a solder material, or the like), or conductive resin, or has a structure in which a plurality of layers comprised of the above material are stacked. The second wiring layer 7 is formed by a sputtering method, a CVD method, a vapor deposition method, a plating method, a printing method, or the like, by using a mask (not shown) with a predetermined pattern. The second wiring layer 7 is desirably formed to fill the through hole 3 with no space left, but may be formed to fill the through hole 3 incompletely with space left.

Thereafter, in an eighth step shown in FIG. 3H, the external terminal 8 is formed on the second wiring layer 7, and the rear surface side protection layer 9 is formed on the second wiring layer 7 except its portion where the external terminal 8 is disposed and on the second insulation layer 6. The external terminal 8 is comprised of, for example, a solder material, and the rear surface side protection layer 9 is comprised of polyimide resin, epoxy resin, or a solder resist material. Subsequently, the semiconductor substrate 2 is cut by a cutting blade of a dicer. Thus, individual pieces of the semiconductor device 1 shown in FIG. 1 is obtained.

In the semiconductor device 1 of the first embodiment manufactured as described above, the second insulation layer 6 covering the inner wall surface of the through hole 3 and the rear surface is formed to be in contact with the inner side of the first wiring layer 5, and has, in its contact portion, the plural small openings 6a smaller in diameter than the opening 4a of the first insulation layer 4, and the second wiring layer 7 filled in the through hole 3 is in contact with the inner side of the first wiring layer 5 and in electrical connection with the first wiring layer 5, via the plural small openings 6a. Therefore, on the front surface side opening of the through hole 3, the second insulation layer 6 functions as a reinforcing structure for the first wiring layer 5. This prevents the first wiring layer 5 from peeling off the front surface side protection layer (not shown) or breaking, which improves yields and makes it possible to manufacture the semiconductor device with high electrical and mechanical reliability.

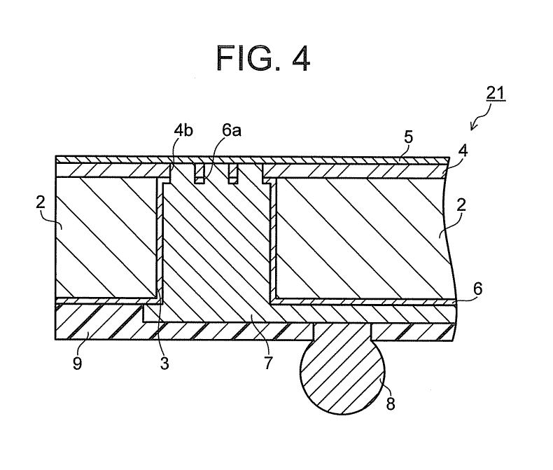

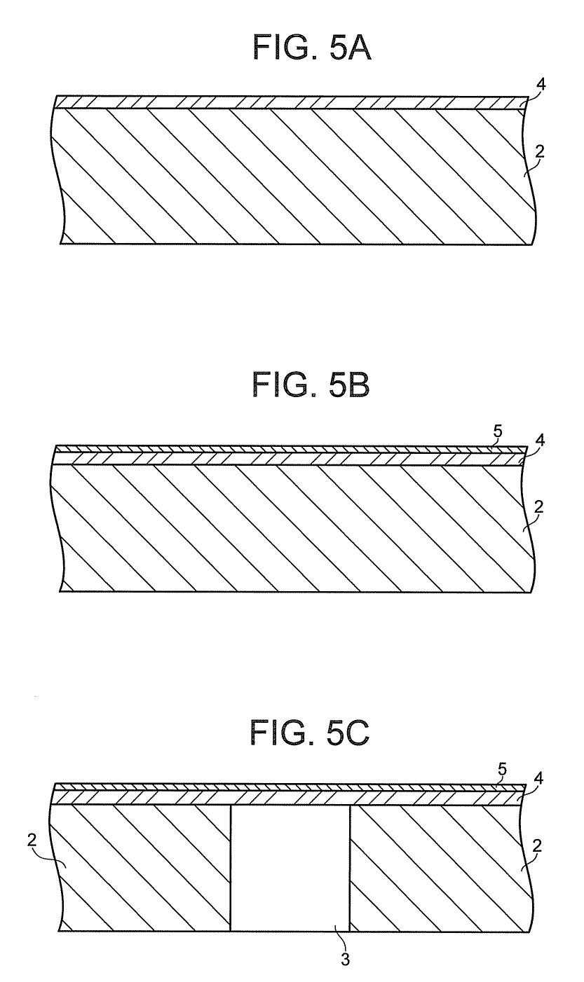

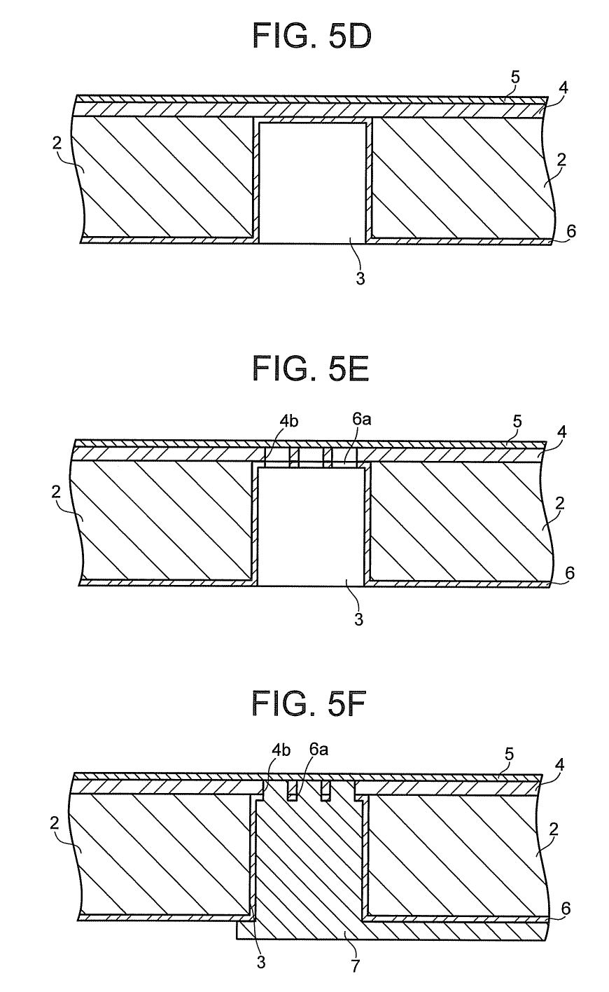

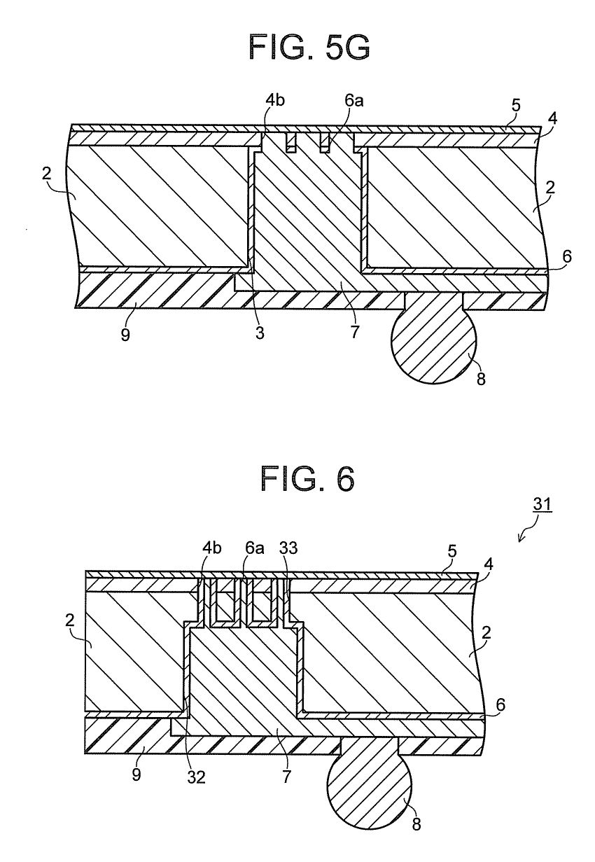

Next, another embodiment of the present invention will be described. FIG. 4 is a cross-sectional view showing the configuration of a semiconductor device according to a second embodiment of the present invention, and FIG. 5A to FIG. 5G are cross-sectional views showing steps of a method of manufacturing the semiconductor device of the second embodiment. In these drawings, the same reference numerals and symbols are used to designate the same portions as those in FIG. 1 and FIG. 3A to FIG. 3H.

As shown in FIG. 4, a semiconductor device 21 of the second embodiment has a semiconductor substrate 2 such as a silicon substrate, and this semiconductor substrate 2 has a through hole 3 formed penetrating through its front surface and rear surface. A first insulation layer 4 is formed on the front surface of the semiconductor substrate 2, the first insulation layer 4 having, on an upper end (front surface side end) of the through hole 3, a plurality of small openings 4b smaller in diameter than the through hole 3. On the first insulation layer 4, a first wiring layer 5 is formed. The first wiring layer 5 is formed to cover and close the plural small openings 4b of the first insulation layer 4. Further, a second insulation layer 6 covers inner wall surface of the through hole 3 and the rear surface of the semiconductor substrate 2. The second insulation layer 6 is formed to be in contact with an inner side of the first insulation layer 4 and its contact portions has a plurality of small openings 6a equal in diameter to the small openings 4b of the first insulation layer 4. The plural small openings 6a of the second insulation layer 6 are formed to be coaxial with the plural small openings 4b of the first insulation layer 4, that is, to overlap at the same positions with the plural small openings 4b when seen from the rear surface side of the semiconductor substrate 2.

The shape, number, and disposition of the small openings 4b of the first insulation layer 4 and the small openings 6a of the second insulation layer 6 are not specifically limited, but as in the above-described first embodiment, it is preferable that the circular small openings 4b, 6a are disposed at intersections (lattice points) of the x direction and the y direction as shown in FIG. 2B.

A second wiring layer 7 is formed to fill the inside of the through hole 3. The second wiring layer 7 is in contact with an inner side of the first wiring layer 5 via the plural small openings 6a of the second insulation layer 6 and the plural small openings 4b of the first insulation layer 4 and is formed on the second insulation layer 6 in the through hole 3 and continuously on the second insulation layer 6 on the rear surface of the semiconductor substrate 2. Further, external terminal 8 is provided on the second wiring layer 7 on the rear surface of the semiconductor substrate 2, and on the rear surface of the semiconductor substrate 9, a protection layer (rear surface side protection layer) 9 covers the second wiring layer 7 except its portion where the external terminal 8 is disposed and the second insulation layer 6.

The semiconductor device 21 of the second embodiment is manufactured in the following manner. Specifically, in a first step shown in FIG. 5A, the first insulation layer 4 comprised of silicon oxide (SiO₂), silicon nitride (SiNₓ), SiOF, porous SiOC, or the like is formed on the front surface of the semiconductor substrate 2 by a CVD method, a spin coating method, a spray coating method, or the like.

Next, in a second step shown in FIG. 5B, the first wiring layer 5 is formed on the first insulation layer 4 by a sputtering method, a CVD method, a vapor deposition method, a plating method, or the like. The first wiring layer 5 is, for example, a single layer comprised of a high-resistance metal (Ti, TiN, TiW, Ni, Cr, TaN, COWP, or the like) or a low-resistance metal (Al, Al—Cu, Al—Si—Cu, Cu, Au, Ag, or the like), or has a structure in which a plurality of layers comprised of the aforethe material are stacked.

Incidentally, after the first wiring layer 5 is formed, a front surface side protection film, though not shown, is formed thereon. The front surface side protection film is comprised of SiO₂, SiNₓ, polyimide resin, epoxy resin, or a solder resist material, and is formed by, for example, a CVD method, a spin coating method, a spray coating method, a printing method, or the like. In a multilayer wiring structure in which an insulation layer and a wiring layer are formed between the first wiring layer 5 and the front surface side protection film, the insulation layer and the wiring layer are formed by a CVD method, a sputtering method, a vapor deposition method, a plating method, or the like. When the multilayer wiring structure is formed, the steps shown in FIG. 5A and FIG. 5B are repeated, and the wiring layers are mutually electrically connected by metal vias, not shown. Further, when the semiconductor device 21 is in a form of an image sensor package, a light-transmitting protection substrate of glass or the like is bonded on the front surface of the semiconductor substrate 2 via a bonding layer (for example, photosensitive or non-photosensitive epoxy resin, polyimide resin, acrylic resin, silicone resin).

Next, in a third step shown in FIG. 5C, the through hole 3 is formed from the rear surface side of the semiconductor substrate 2 by a plasma etching method by using a mask (not shown) with a predetermined pattern to expose the first insulation layer 4. The through hole 3 preferably has a cross section tapering toward the first insulation layer 4. In the plasma etching for forming the through hole 3, etching gas (for example, mixed gas of SF₆, O₂, and Ar when the semiconductor substrate 2 is a silicon substrate and the first insulation layer 4 is a SiO₂ film) is introduced into plasma so that the semiconductor substrate 2 is etched to a relatively larger extent than the first insulation layer 4.

In a fourth step shown in FIG. 5D, the second insulation layer 6 is formed by a CVD method, a spray coating method, a spin coating method, a film laminating method, or the like to cover the bottom surface (exposed portion of the first insulation layer 4) and the inner wall surface of the through hole 3, and the rear surface of the semiconductor substrate 2. The second insulation layer 6 is comprised of, for example, silicon oxide, silicon nitride, polyimide resin, BCB (benzocyclobuten) resin, epoxy resin, or the like.

Next, in a fifth step shown in FIG. 5E, by plasma etching using a mask (not shown) with a predetermined pattern, the plural small openings 6a smaller in diameter than the front surface side opening of the through hole 3 are formed in of the second insulation layer 6, which is positioned on the bottom surface of the through hole 3 to cover the first wiring layer 5, thereby exposing the first insulation layer 4 from the small openings 6a. Thereafter, the first insulation layer 4 thus exposed is etched, thereby forming the small openings 4b equal in diameter to the small openings 6a at the same positions as the small openings 6a. In the plasma etching for forming the small openings 6a of the second insulation layer 6 and the small openings 4b of the first insulation layer 4, etching gas (for example, mixed gas of C₅F₈, O₂, and Ar when the second insulation layer 6 and the first insulation layer 4 are comprised SiO₂ and the first wiring layer 5 is comprised of TiN or Al) is introduced into plasma so that the second insulation layer 6 and the first insulation layer 4 are etched to a relatively larger extent than the first wiring layer 5.

Incidentally, the above-described fifth step can be performed by a laser etching method, without using any mask. As a laser beam source, YAG laser, UV laser, excimer laser, carbon dioxide (CO₂) laser, or the like is used, for instance. When the second insulation layer 6 is made of a resin film and the small openings 6a have minute diameters, UV laser with a 266 nm wavelength is preferably used.

In a sixth step shown in FIG. 5F, the second wiring layer 7 is formed on the second insulation layer 6 in the through hole 3 and continuously on the second insulation layer 6 on the rear surface of the semiconductor substrate 2 so as to be in contact with the inner side of the first wiring layer 5 via the small openings 6a of the second insulation layer 6 and the small openings 4b of the first insulation layer 4. The second wiring layer 7 is, for example, a single layer comprised of a high-resistance metal (Ti, TiN, TiW, Ni, Cr, TaN, COWP, or the like), a low-resistance metal (Al, Al—Cu, Al—Si—Cu, Cu, Au, Ag, a solder material, or the like), or conductive resin, or has a structure in which a plurality of layers comprised of the above material are stacked. The second wiring layer 7 is formed by a sputtering method, a CVD method, a vapor deposition method, a plating method, a printing method, or the like, by using a mask (not shown) with a predetermined pattern. The second wiring layer 7 is desirably formed to fill the through hole 3 with no space left, but may be formed to fill the through hole 3 incompletely with space left.

Thereafter, in a seventh step shown in FIG. 5G, the external terminal 8 is formed on the second wiring layer 7, and the rear surface side protection layer 9 is formed on the second wiring layer 7 except its portion where the external terminal 8 is disposed and on the second insulation layer 6. The external terminal 8 is comprised of, for example, a solder material, and the rear surface side protection layer 9 is comprised of polyimide resin, epoxy resin, or a solder resist material. Next, the semiconductor substrate 2 is cut by a cutting blade of a dicer. Thus, individual piece of the semiconductor device 21 shown in FIG. 4 is obtained.

In the semiconductor device 21 of the second embodiment manufactured as described above, the second insulation layer 6 has an effect of reinforcing the first wiring layer 5 as in the first embodiment, and in addition, the first insulation layer 4 having the plural small openings 4b equal in diameter to and provided at the same position as the small openings 6a of the second insulation layer 6 is formed to be in contact with the inner side of the first wiring layer 5, and portion where the first insulation layer 4 and the second insulation layer 6 are stacked function as a reinforcing structure for the first wiring layer 5. Therefore, the reinforcing effect for the first wiring layer 5 is still higher than that of the first embodiment, and the semiconductor device with still higher electrical and mechanical reliability can be obtained.

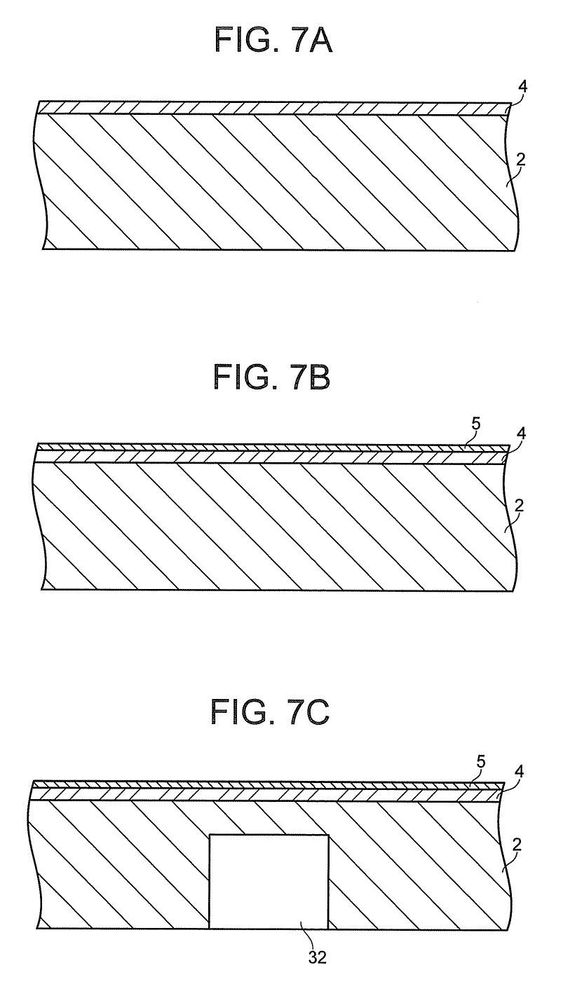

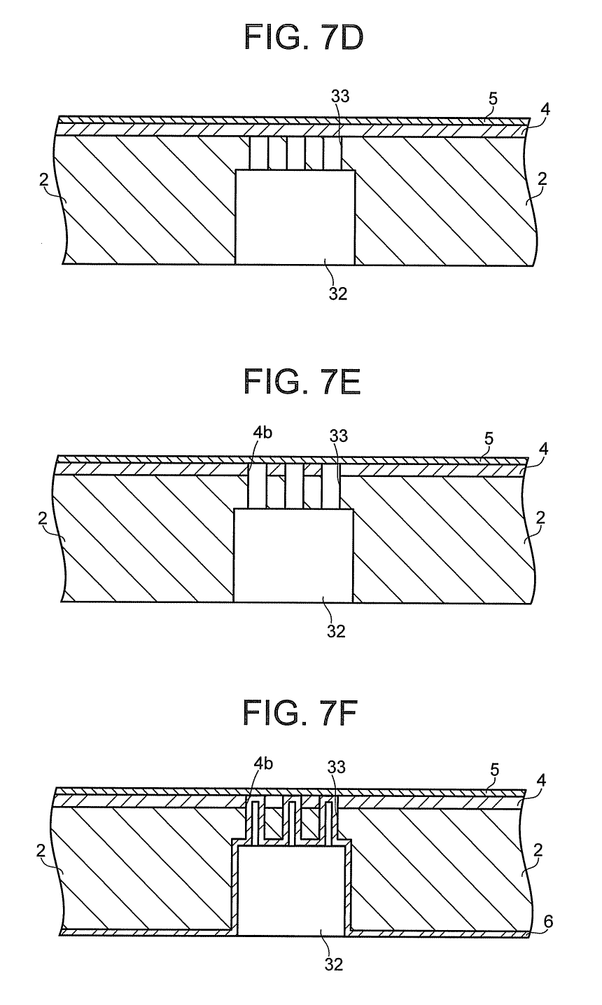

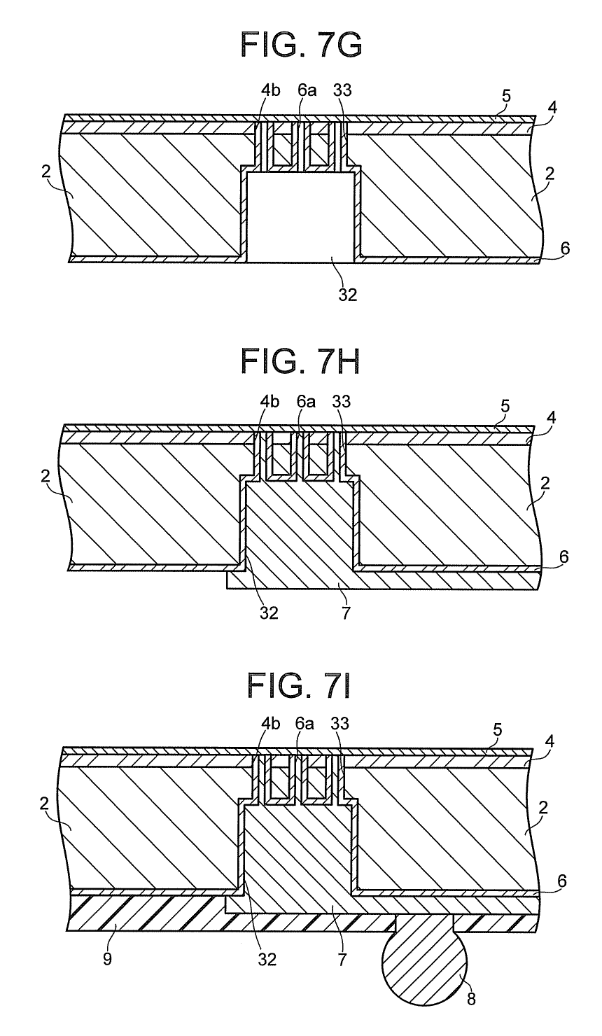

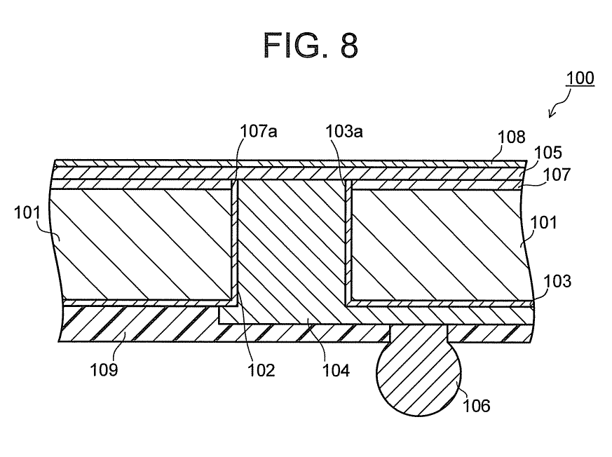

FIG. 6 is a cross-sectional view showing a configuration of a semiconductor device according to a third embodiment of the present invention, and FIG. 7A to FIG. 7I are cross-sectional views showing steps of a method of manufacturing the semiconductor device of the third embodiment. In these drawings, the same reference numerals and symbols are used to designate the same portions as those in FIG. 1 and FIG. 3A to FIG. 3H (and FIG. 4 and FIG. 5A to FIG. 5G).

As shown in FIG. 6, a semiconductor device 31 of the third embodiment has a semiconductor substrate 2 such as a silicon substrate, and this semiconductor substrate 2 has a recessed hole 32 having a depth smaller than a thickness of the semiconductor substrate 2 formed from a rear surface side. A plurality of small through holes 33 smaller in diameter than the recessed hole 32 are formed in a bottom (front surface side end)of the recessed hole 32 to penetrate through a front surface side portion of the semiconductor substrate 2. The shape, number, and disposition of the small through holes 33 are not specifically limited, but it is preferable that the circular small through holes 33 are disposed at lattice points of the x axis and the y axis as shown in FIG. 2B.

A front surface of the semiconductor substrate 2 is covered by a first insulation layer 4 having small openings 4b equal in diameter to the small through holes 33. The plural small openings 4b of the first insulation layer 4 are formed to be adjacent to upper ends (front surface side openings) of the small through holes 33. On the first insulation layer 4, a first wiring layer 5 is formed to cover and close the plural small openings 4b.

Further, inner wall surface of the recessed hole 32 and the plural small through holes 33 and the rear surface of the semiconductor substrate 2 are covered by a second insulation layer 6. The second insulation layer 6 is formed so that its portions on the front surface side ends of the plural small through holes 33 are in contact with an inner side of the first wiring layer 5, and in its contact portion, a plurality of small openings 6a substantially equal in diameter to the plural small openings 4b of the first insulation layer 4 (smaller in diameter by a thickness of the second insulation layer 6) are formed.

Further, a second wiring layer 7 is formed to fill the inside of the recessed hole 32 and the small through holes 33 formed to be adjacent to the recessed hole 32. The second wiring layer 7 is in contact with an inner side of the first wiring layer 5 via the small openings 6a of the second insulation layer 6 and is formed on the second insulation layer 6 in the small through holes 33 and the recessed hole 32 and continuously on the second insulation layer 6 on the rear surface of the semiconductor substrate 2. An external terminal 8 is provided on the second wiring layer 7 on the rear surface of the semiconductor substrate 2, and on the rear surface of the semiconductor substrate 2, a protection layer (rear surface side protection layer) 9 covers the second wiring layer 7 except its portions where the external terminal 8 is disposed and the second insulation layer 6.

The semiconductor device 31 of the third embodiment is manufactured in the following manner. In a first step shown in FIG. 7A, the first insulation layer 4 comprised of silicon oxide, silicon nitride, SiOF, porous SiOC, or the like is formed on the front surface of the semiconductor substrate 2 by a CVD method, a spin coating method, a spray coating method, or the like.

Next, in a second step shown in FIG. 7B, the first wiring layer 5 is formed on the first insulation layer 4 by a sputtering method, a CVD method, a vapor deposition method, a plating method, or the like. The first wiring layer 5 is, for example, a single layer comprised of a high-resistance metal (Ti, TiN, TiW, Ni, Cr, TaN, COWP, or the like) or a low-resistance metal (Al, Al—Cu, Al—Si—Cu, Cu, Au, Ag, or the like), or has a structure in which a plurality of layers comprised of the aforethe material are stacked.

Incidentally, after the first wiring layer 5 is formed, a front surface side protection film, though not shown, is formed thereon. The front surface side protection film is comprised of SiO₂, SiNₓ, a polyimide resin, epoxy resin, or a solder resist material, and is formed by, for example, a CVD method, a spin coating method, a spray coating method, a printing method, or the like. In a multilayer wiring structure in which an insulation layer and a wiring layer are formed between the first wiring layer 5 and the front surface side protection film, the insulation layer and the wiring layer are formed by a CVD method, a sputtering method, a vapor deposition method, a plating method, or the like. When the multilayer wiring structure is formed, the steps shown in FIG. 7A and FIG. 7B are repeated, and the wiring layers are mutually electrically connected by metal vias, not shown. Further, when the semiconductor device 31 is in a form of an image sensor package, a light-transmitting protection substrate of glass or the like is bonded on the front surface of the semiconductor substrate 2 via a bonding layer (for example, photosensitive or non-photosensitive epoxy resin, polyimide resin, acrylic resin, silicone resin).

Next, in a third step shown in FIG. 7C, the recessed hole 32 whose depth is set smaller than the thickness of the semiconductor substrate 2 is formed from the rear surface side of the semiconductor substrate 2 by a plasma etching method by using a mask (not shown) with a predetermined pattern. Preferably, each of the recessed hole 32 has a cross section tapering toward the first insulation layer 4. In the plasma etching for forming the recessed hole 32, etching gas is introduced into plasma. For example, when the semiconductor substrate 2 is a silicon substrate, mixed gas of SF₆, O₂, and Ar is used as the etching gas.

Next, in a fourth step shown in FIG. 7D, the plural small through holes 33 smaller in diameter than the recessed hole 32 are formed in the bottom (upper portion in the drawing) of the recessed hole 32 by a plasma etching method by using a mask (not shown) with a predetermined pattern from the rear surface side of the semiconductor substrate 2. Then, the first insulation layer 4 is exposed from bottom surfaces of the small through holes 33. In the plasma etching for forming the small through holes 33, etching gas is introduced into plasma so that the semiconductor substrate 2 is etched to a larger extent than the first insulation layer 4. For example, when the semiconductor substrate 2 is a silicon substrate and the first insulation layer 4 is a SiO₂ film, mixed gas of SF₆, O₂, and Ar is used as the etching gas.

Next in a fifth step shown in FIG. 7E, the exposed portions of the first insulation layer 4 are removed by plasma etching, thereby forming the small openings 4b in the first insulation layer 4, so that the first wiring layer 5 is exposed from these small openings 4b. In this plasma etching, etching gas (for example, mixed gas of C₅F₈, O₂, and Ar when the first insulation layer 4 is a SiO₂ film, the semiconductor substrate is a silicon substrate, and the first wiring layer 5 is made of TiN or Al) is introduced into plasma so that the first insulation layer 4 is etched to a relatively larger extent than the semiconductor substrate 2 and the first wiring layer 5.

Incidentally, the above-described fourth and fifth steps can be performed at a time by a laser etching method without using any mask. As a laser beam source, YAG laser, UV laser, excimer laser, carbon dioxide (CO₂) laser, or the like is used, for instance. When the semiconductor substrate 2 is a silicon substrate and the first insulation layer 4 is a SiO₂ film, YAG laser with a 355 nm wavelength is preferably used as the laser beam source.

Next, in a sixth step shown in FIG. 7F, the second insulation layer 6 is formed by a CVD method, a spray coating method, a spin coating method, a film laminating method, or the like to cover the bottom surfaces (exposed portions of the first wiring layer 5) and the inner wall surfaces of the small through holes 33, the inner wall surface of the recessed hole 32, and the rear surface of the semiconductor substrate 2. The second insulation layer 6 is comprised of, for example, silicon oxide, silicon nitride, polyimide resin, BCB (benzocyclobuten) resin, epoxy resin, or the like.

In a seventh step shown in FIG. 7G, by plasma etching using a mask (not shown) with a predetermined pattern, the plural small openings 6a equal in diameter to the small through holes 33 and the small openings 4b of the first insulation layer 4 are formed in the second insulation layer 6, which are positioned on the bottom surfaces of the small through holes 33 to cover the first wiring layer 5, whereby the first wiring layer 5 is exposed again. In the plasma etching for forming the small openings 6a, etching gas (for example, mixed gas of C₅F₈, O₂, and Ar when the second insulation layer 6 is a SiO₂ film and the first wiring layer 5 is comprised of TiN or Al) is introduced into plasma so that the second insulation layer 6 is etched to a larger extent than the first wiring layer 5.

In order to remove the second insulation layer 6 to form the small openings 6a, the second insulation layer 6 may be etched back by anisotropic etching without using any mask. In this case, it is preferable to form the second insulation layer 6 so that its portions on the bottom surface and the inner wall surface of the recessed hole 32 and on the rear surface of the semiconductor substrate 2 are larger in thickness than its portions on the bottom surfaces and the inner wall surfaces of the small through holes 33.

Next, in an eighth step shown in FIG. 7H, the second wiring layer 7 is formed on the second insulation layer 6 in the plural small through holes 33 and continuously on the second insulation layer 6 on the rear surface of the semiconductor substrate 2 so as to be in contact with the inner side of the first wiring layer 5 via the small openings 6a of the second insulation layer 6. The second wiring layer 7 is, for example, a single layer comprised of a high-resistance metal (Ti, TiN, TiW, Ni, Cr, TaN, COWP, or the like), a low-resistance metal (Al, Al—Cu, Al—Si—Cu, Cu, Au, Ag, a solder material, or the like), or conductive resin, or has a structure in which a plurality of layers comprised of the above material are stacked. The second wiring layer 7 is formed by a sputtering method, a CVD method, a vapor deposition method, a plating method, a printing method, or the like, by using a mask (not shown) with a predetermined pattern so as to fill the inside of the recessed hole 32 and the small through holes 33. The second wiring layer 7 is desirably formed to fill the inside of the recessed hole 32 and the small through holes 33 with no space left, but may be formed to fill the inside incompletely with space left.

Thereafter, in a ninth step shown in FIG. 7I, the external terminal 8 is formed on the second wiring layer 7, and the rear surface side protection layer 9 is formed on the second wiring layer 7 except its portion where the external terminal 8 is disposed and on the second insulation layer 6. The external terminal 8 is comprised of, for example, a solder material, and the rear surface side protection layer 9 is comprised of polyimide resin, epoxy resin, or a solder resist material. Subsequently, the semiconductor substrate 2 is cut by a cutting blade of a dicer. Individual piece of the semiconductor device 31 shown in FIG. 6 are obtained.

In the semiconductor device 31 of the third embodiment manufactured as described above, on the bottom surface (upper surface in the drawings) of the recessed hole 32 which is formed from the rear surface side of the semiconductor substrate 2 so as to have the depth smaller than the thickness of the semiconductor substrate 2, the plural small through holes 33 smaller in diameter than the recessed hole 32 are formed, the plural small openings 4b of the first insulation layer 4 are formed to be adjacent to the upper portions of the small through holes 33, and the second insulation layer 6 formed to cover the inner wall surfaces of the recessed hole 32 and the small through holes 33 has, in each of its portions in contact with the inner side of the first wiring layer 5, the plural small openings 6a equal in diameter to the small through holes 33 and the small openings 4b of the first insulation layer 4. Therefore, portions corresponding to the depth of the small through holes 33, which are above the bottom surface (upper surface in the drawings) of the recessed hole 32 of the semiconductor substrate 2, support the first insulation layer 4 in contact with the inner side of the first wiring layer 5. That is, on the portion where the recessed hole 32 and so on are formed, portions where the first insulation layer 4 and the formation portions of the small through holes 33 are stacked function, together with the second insulation layer 6, as a reinforcing structure for the first wiring layer 5. Therefore, the effect of reinforcing the first wiring layer 5 is still higher than that of the second embodiment, and the semiconductor device with still higher electrical and mechanical reliability can be obtained.

The structures, shapes, sizes, and disposition relations described in the foregoing embodiments are presented only schematically, and the numerical values and the compositions (materials) of the structures are only given as examples. Therefore, the present invention is not limited to the above-described embodiments, and the embodiments can be modified into various forms without departing from the scope of the technical ideas shown in the claims.

What is claimed is:

1. A semiconductor device, comprising:
a semiconductor substrate;
a through hole penetrating through a first surface and a second surface of the semiconductor substrate;
a first insulation layer having an opening on a first surface side opening of the through hole, formed on the first surface of the semiconductor substrate;
a first conductor layer formed on the first insulation layer to cover the opening;
a second insulation layer having a plurality of small openings smaller in diameter than the opening of the first insulation layer, formed on an inner wall surface of the through hole and continuously on the second surface of the semiconductor substrate; and
a second conductor layer formed to be in contact with an inner side of the first conductor layer via the small openings of the second insulation layer and to extend on the second insulation layer in the through hole and continuously on the second insulation layer on the second surface of the semiconductor substrate.

2. The semiconductor device according to claim 1,
wherein the second insulation layer internally contacts the first conductor layer via the opening of the first insulation layer, and has the small openings in the internal contact portion.

3. The semiconductor device according to claim 1,
wherein the plural small openings of the second insulation layer are disposed at lattice points of x-y axes.

4. The semiconductor device according to claim 1,
wherein a protection film (front surface side protection film) is formed on the first conductor layer.

5. The semiconductor device according to claim 4,
wherein a multilayer wiring portion is formed between the first conductor layer and the protection film (surface side protection film).

6. The semiconductor device according to claim 1,
wherein the first insulation layer has, on the first surface side opening of the through hole, a plurality of small openings smaller in diameter than the first surface side opening;
wherein the second insulation layer is formed to contact internally a surface facing the semiconductor substrate, of the first insulation layer, and in the internal contact portion the plural small openings are formed so as to communicate with the small openings of the first insulation layer; and
wherein the second conductor layer internally contacts the first conductor layer via the small openings of the second insulation layer and the small openings of the first insulation layer.

7. The semiconductor device according to claim 6,
wherein the small openings of the second insulation layer are equal in diameter to and are coaxial with the small openings of the first insulation layer.

8. The semiconductor device according to claim 6,
wherein the plural small openings of the second insulation layer are disposed at lattice points of x-y axes.

9. The semiconductor device according to claim 6,
wherein a protection film (front surface side protection film) is formed on the first conductor layer.

10. The semiconductor device according to claim 9,
wherein a multilayer wiring portion is formed between the first conductor layer and the protection film (front surface side protection film).

11. A semiconductor device, comprising:
a semiconductor substrate having a first surface and a second surface;
a recessed hole formed from the second surface of the semiconductor substrate and having a depth smaller than a thickness of the semiconductor substrate;
a plurality of small through holes formed on a bottom of the recessed hole to penetrate through a first surface side portion of the semiconductor substrate, and being smaller in diameter than the recessed hole;
a first insulation layer formed on the first surface of the semiconductor substrate and having, on first surface side openings of the small through holes, small openings equal in diameter to the first surface side openings of the small through holes;
a first conductor layer formed on the first insulation layer to cover the small openings;
a second insulation layer which is formed to contact the first conductor layer internally via the small openings of the first insulation layer and to extend on inner wall surfaces of the recessed hole and the small through holes and continuously on the second surface of the semiconductor substrate, and which has, in the internal contact portion, a plurality of small openings substantially equal in diameter to the plural small openings of the first insulation layer; and
a second conductor layer formed to be in contact with the inner side of the first conductor layer via the plural small openings of the second insulation layer and to extend on the second insulation layer in the recessed hole and the small through holes and continuously on the second insulation layer on the second surface of the semiconductor substrate.

12. The semiconductor device according to claim 11,
wherein the plural small through holes of the semiconductor substrate are disposed at lattice points of x-y axes.

13. The semiconductor device according to claim 11,
wherein a protection film (front surface side protection film) is formed on the first conductor layer.

14. The semiconductor device according to claim 13,
wherein a multilayer wiring portion is formed between the first conductor layer and the protection film (front surface side protection film).

15. A method of manufacturing a semiconductor device, comprising:
forming a first insulation layer on a first surface of a semiconductor substrate;
forming a first conductor layer on the first insulation layer;
forming a through hole from a second surface side to the first surface side of the semiconductor substrate to expose the first insulation layer from a first surface side end of the through hole;
forming an opening in the first insulation layer;
forming a second insulation layer on an inner wall surface of the through hole and continuously on the second surface of the semiconductor substrate;
forming a plurality of small openings in the second insulation layer to expose the first conductor layer; and
forming a second conductor layer in a manner that the second conductor layer is in contact with an inner side of the first conductor layer via the small openings of the second insulation layer and extends on the second insulation layer in the through hole and continuously on the second insulation layer on the second surface of the semiconductor substrate.

16. The method of manufacturing the semiconductor device according to claim 15, comprising:
after forming the through hole from the second surface side to the first surface side of the semiconductor substrate, forming the opening in an exposed portion of the first insulation layer to expose the first conductor layer;
forming the second insulation layer on the exposed first conductor layer, the inner wall surface of the through hole, and on the second surface of the semiconductor substrate; and
forming the plural small openings smaller in diameter than the opening of the first insulation layer, in a portion, of the second insulation layer, positioned on an exposed portion of the first conductor layer to expose the first conductor layer again.

17. The method of manufacturing the semiconductor device according to claim 15, comprising:
after forming the through hole from the second surface side to the first surface side of the semiconductor substrate to expose the first insulation layer, forming the second insulation layer on an exposed portion of the first insulation layer, the inner wall surface of the through hole, and the second surface of the semiconductor substrate;
after forming the plural small openings smaller in diameter than the through hole, in a portion, of the second insulation layer, positioned on the exposed portion of the first insulation layer, forming, in the first insulation layer, small openings equal in diameter to and adjacent to the small openings of the second insulation layer, to expose the first conductor layer; and
forming the second conductor layer in a manner that the second conductor layer is in contact with the inner side of the first conductor layer via the small openings of the second insulation layer and the small openings of the first insulation layer.

18. The method of manufacturing the semiconductor device according to claim 15,
wherein the forming the through hole in the semiconductor substrate includes:
forming a recessed hole having a depth smaller than a thickness of the semiconductor substrate, from the second surface side of the semiconductor substrate; and
forming, on a first surface side end of the recessed hole, a plurality of small through holes smaller in diameter than the recessed hole in a manner that the small through holes penetrate through a first surface side portion of the semiconductor substrate; wherein the method further comprises:
after the forming the small through holes, forming a plurality of small openings in the first insulation layer to expose the first conductor layer, the small openings being equal in diameter to and adjacent to the small through holes;
forming the second insulation layer in a manner that the second insulation layer covers inner wall surfaces of the recessed hole and the small through holes and the second surface of the semiconductor substrate and is in contact with the inner side of the exposed first conductor layer;
forming the plural small openings in a portion, of the second insulation layer, in contact with the inner side of the first conductor layer, to expose the first conductor layer again, the small openings being substantially equal in diameter to the small openings of the first insulation layer; and
forming the second conductor layer in a manner that the second conductor layer is in contact with the inner side of the first conductor layer via the small openings of the second insulation layer.

19. The method of manufacturing the semiconductor device according to claim 15, further comprising forming a protection film (front surface side protection film) on the first conductor layer.

20. The method of manufacturing the semiconductor device according to claim 19, further comprising forming a multilayer wiring portion between the first conductor layer and the protection film (surface side protection film).
